(19) United States
(12) Patent Application Publication
(10) Pub. No.: US 2013/0146975 A1
(43) Pub. Date: Jun. 13, 2013

(54) SEMICONDUCTOR DEVICE AND INTEGRATED CIRCUIT WITH HIGH-K/METAL GATE WITHOUT HIGH-K DIRECT CONTACT WITH STI

(71) Applicants: Kangguo Cheng, Albany, NY (US); Bruce B. Doris, Albany, NY (US); Ali Khakifirooz, San Jose, CA (US); Pranita Kulkarni, Albany, NY (US)

(72) Inventors: Kangguo Cheng, Albany, NY (US); Bruce B. Doris, Albany, NY (US); Ali Khakifirooz, San Jose, CA (US); Pranita Kulkarni, Albany, NY (US)

(73) Assignee: International Business Machines Corporation, Armonk, NY (US)

(21) Appl. No.: 13/316,677

(22) Filed: Dec. 12, 2011

(51) Int. Cl. H01L 27/088; H01L 21/762

(52) U.S. Cl. 257/347; 438/424; 257/368; 257/E27.06; 257/E21.546

(57) ABSTRACT

A method, semiconductor device, and integrated circuit with a high-k/metal gate without high-k direct contact with STI. A high-k dielectric and a pad film are deposited directly onto a semiconductor substrate. Shallow trench isolation is performed, with shallow trenches etched directly into the pad film, the high-k material, and the substrate. The shallow trench is lined with an oxygen diffusion barrier and is subsequently filled with an insulating dielectric material. Thereafter the pad film and the insulating dielectric are recessed to a point where the oxygen diffusion barrier still remains between the insulating dielectric and the high-k material, preventing any contact there between. Afterwards a conductive gate is formed overlying the device.

### BACKGROUND OF THE INVENTION

1. Field of the Invention

The present invention generally relates to a semiconductor device, and more specifically to the use of shallow trench isolation between semiconductor devices.

2. Description of Related Art

Many semiconductor devices manufactured today are metal oxide semiconductor field effect transistor devices, commonly referred to as MOSFET devices. Integrated circuits are often made up of an array of connected field effect transistors (FETs) or more specifically MOSFETS. Such MOSFET devices can be p-type devices and n-type devices, and often a semiconductor device will include both, forming what is known as a complimentary MOS device, or CMOS device.

The gate electrode of an FET device is formed adjacent to the channel region of the device and separated by a thin insulating layer. In the past, this insulating layer has primarily been a silicon dioxide gate dielectric. As miniaturization of semiconductor devices has significantly progressed, the size of the insulating layer has shrunken. At a low enough thickness of the silicon dioxide insulating layer, high leakage currents due to tunneling of charge carriers through the insulating layer become a major problem, significantly degrading device performance. In high end devices, such degradation is not acceptable.

One way around to address this problem is by increasing the dielectric constant of the insulating gate material. For this purpose, the use of so called high-k materials has been shown to work effectively as gate insulators. Use of a high-k material allows the FET to maintain an insulating gate layer of an appropriate thickness to avoid leakage currents while simultaneously allowing a sufficient drive current.

Shallow trench isolation is a technique used where shallow trenches are etched into a pattern in the semiconductor device and subsequently filled with an insulating dielectric material. This technique is especially useful when manufacturing CMOS devices, and is used to stop current leakage between adjacent FETs.

One of the challenges of manufacturing high-k FETs with shallow trench isolation is avoiding the degradation of the high-k material itself due to oxygen incorporating into the high-k. A primary source of oxygen during the manufacturing process is the shallow trench isolation, which is typically filled with silicon dioxide.

### BRIEF SUMMARY OF THE INVENTION

To overcome these deficiencies, the present invention provides A method of manufacturing a semiconductor device, the method including: depositing a high-k dielectric and a pad layer on a substrate having semiconductor material, resulting in a stack; forming an isolation trench in the stack; lining the isolation trench sidewalls with a material that forms an oxygen diffusion barrier; filling the lined isolation trenches with a first dielectric material; etching the first dielectric material to equalize the remaining first dielectric material and high-k dielectric levels; etching the pad film and the isolation trench liner to completely remove the pad film and equalize the liner and high-k dielectric levels; and forming a metal gate overlying at least a portion of the high-k dielectric and the first dielectric material.

According to another aspect, the present invention provides A semiconductor device including: a semiconductor substrate; a high-k dielectric deposited over the substrate; a lined isolation trench etched into the layers of the high-k material and the semiconductor substrate and filled with a dielectric material; wherein the lined isolation trench extends fully into the high-k dielectric and at least partially into the semiconductor substrate; wherein the liner of the isolation trench is an oxygen diffusion barrier; and wherein the high-k dielectric is separated from the dielectric material by the liner of the isolation trench.

According to yet another aspect, the present invention provides An integrated circuit including: at least two field effect transistors, each including: a semiconductor substrate; a high-k dielectric deposited over the substrate; a lined isolation trench etched into the layers of the high-k material and the semiconductor substrate and filled with a dielectric material; wherein the lined isolation trench extends fully into the high-k dielectric and at least partially into the semiconductor substrate; wherein the liner of the isolation trench is an oxygen diffusion barrier; and wherein the high-k dielectric is separated from the dielectric material by the liner of the isolation trench; and a metal gate on each of the field effect transistors; wherein the metal gates on each of the field effect transistors are electrically connected to form the integrated circuit.

### BRIEF DESCRIPTION OF THE SEVERAL VIEWS OF THE DRAWINGS

FIG. 1 is a cross sectional view of a fabrication step of a semiconductor device prior to the shallow trench isolation definition.

FIG. 2 is a cross sectional view of a fabrication step of a semiconductor device after the shallow trench isolation definition.

FIG. 3 is a cross sectional view of a fabrication step of a semiconductor device with the shallow trench filled and planarized.

FIG. 4 is a cross sectional view of a fabrication step of a semiconductor device after the recession and stripping of the shallow trench isolation and pad film.

FIG. 5a is a top view of a fabrication step of a semiconductor device with a dummy gate formed.

FIG. 5b is a cross sectional side view of a fabrication step of a semiconductor device with a dummy gate formed.

FIG. 5c is a cross sectional front view of a fabrication step of a semiconductor device with a dummy gate formed.

FIG. 6a is a top view of a fabrication step of a semiconductor device with a spacer and a source/drain formed.

FIG. 6b is a cross sectional side view of a fabrication step of a semiconductor device with a spacer and a source/drain formed.

FIG. 6c is a cross sectional front view of a fabrication step of a semiconductor device with a spacer and a source/drain formed.

FIG. 7a is a top view of a fabrication step of a semiconductor device with a dielectric deposited around the dummy gate and spacer that is subsequently planarized.

FIG. 7b is a cross sectional side view of a fabrication step of a semiconductor device with a dielectric deposited around the dummy gate and spacer that is subsequently planarized.

FIG. 7c is a cross sectional front view of a fabrication step of a semiconductor device with a dielectric deposited around the dummy gate and spacer that is subsequently planarized.

FIG. 8a is a top view of a fabrication step of a semiconductor device with the dummy gate removed and replaced by a gate conductor.

FIG. 8b is a cross sectional side view of a fabrication step of a semiconductor device with the dummy gate removed and replaced by a gate conductor.

FIG. 8c is a cross sectional front view of a fabrication step of a semiconductor device with the dummy gate removed and replaced by a gate conductor.

### DETAILED DESCRIPTION OF THE PREFERRED EMBODIMENTS

Various illustrative embodiments of the invention are described below. In the manufacturing of an actual implementation, various modifications will of course be made which are specific to that process. In the interest of clarity, not all techniques have been fully described which are known and obvious to those skilled in the art.

The various embodiments described herein describe techniques to fabricate MOSFET devices, including but not limited to CMOS transistor devices, nMOS transistor devices, and pMOS transistor devices. The term MOS transistor device will be used to refer to any semiconductor device which has a conductive gate positioned on top of a gate insulator positioned on top of a semiconductor substrate.

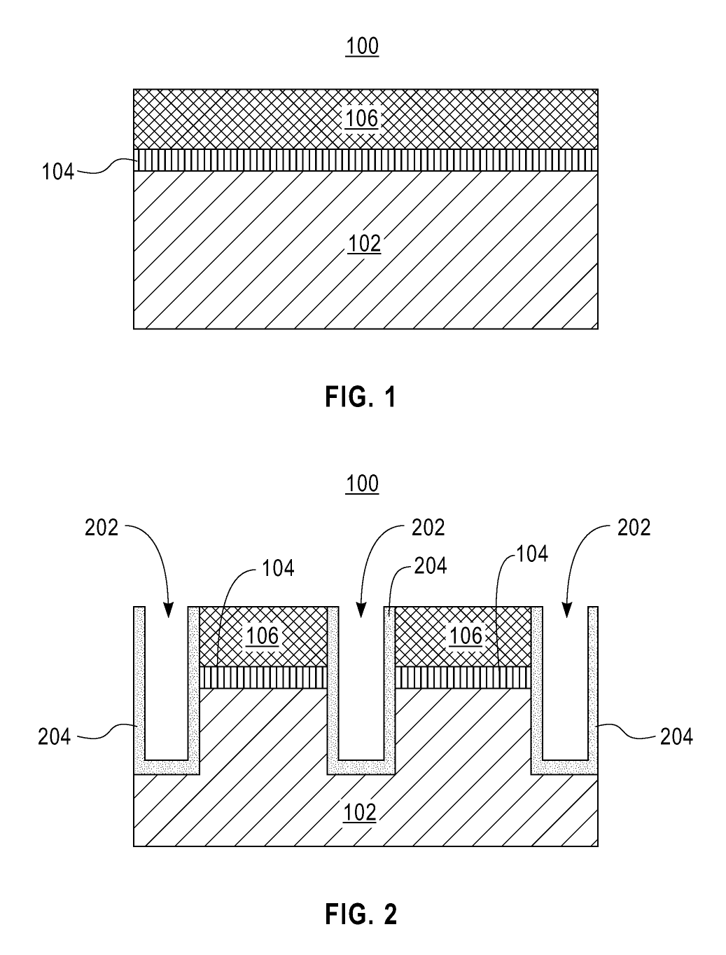

Referring now to FIG. 1, a semiconductor substrate 102 is provided. In an embodiment, the semiconductor substrate can be a silicon-on-insulator (SOI) substrate, where a silicon material is built on top of a layer of insulating material, such as silicon dioxide or aluminum oxide. In another embodiment, the semiconductor substrate 102 can be a strained silicon-on-insulator (sSOI) substrate. In other embodiments, the semiconductor substrate 102 can be a bulk semiconductor substrate, including silicon, germanium, and the like. The semiconductor substrate can also be a III-V semiconductor or a II-VI semiconductor. The embodiments described herein are not restricted to any specific semiconductor substrate configuration unless explicitly stated in an embodiment or the claims.

Fabrication begins in FIG. 1 after providing the semiconductor substrate 102. In a next step, a high-k material 104 is deposited on top of the semiconductor substrate 102. Hereinafter, the term high-k material is used to refer to any material with a high dielectric constant relative to silicon dioxide (i.e. a material with a dielectric constant greater than 3.9). Such materials are well known in the industry, and in an embodiment, hafnium oxide (HfO₂) is used as the high-k material 104. In other embodiments, the high-k material 104 can be hafnium silicate, hafnium silicon oxynitride, zirconium silicate, zirconium oxide, and the like. The high-k material can be deposited by any number of known techniques, including atomic layer deposition (ALD) or an appropriate chemical vapor deposition (CVD) technique, such as metal organic chemical vapor deposition (MOCVD), and atomic layer chemical vapor deposition (ALCVD). In an embodiment, the high-k material 104 is deposited to a thickness of about 10-35 Angstroms, depending on the application. In one embodiment, the deposition technique used deposits one high-k material 104 uniformly over the entire substrate 102. In another embodiment, the deposition technique used deposits more than one high-k material on the substrate 102, forming areas overlying the substrate 102 with different high-k materials.

After the high-k material 104 is deposited on top of the substrate 102, a pad film 106 is deposited on top of the high-k material 104. In an embodiment, the pad film 106 can be silicon nitride. The pad film 106 can be deposited by any number of known techniques, including rapid thermal chemical vapor deposition (RTCVD), physical vapor deposition (PVD), and low pressure chemical vapor deposition (LPCVD). The pad film is deposited to a thickness in a range of 25-100 nanometers, and deposited over the entire surface of the high-k material 104. Together, the substrate 102, high-k material 104 and pad film 106 combine to form a stack, which is the device 100 in an early manufacturing stage.

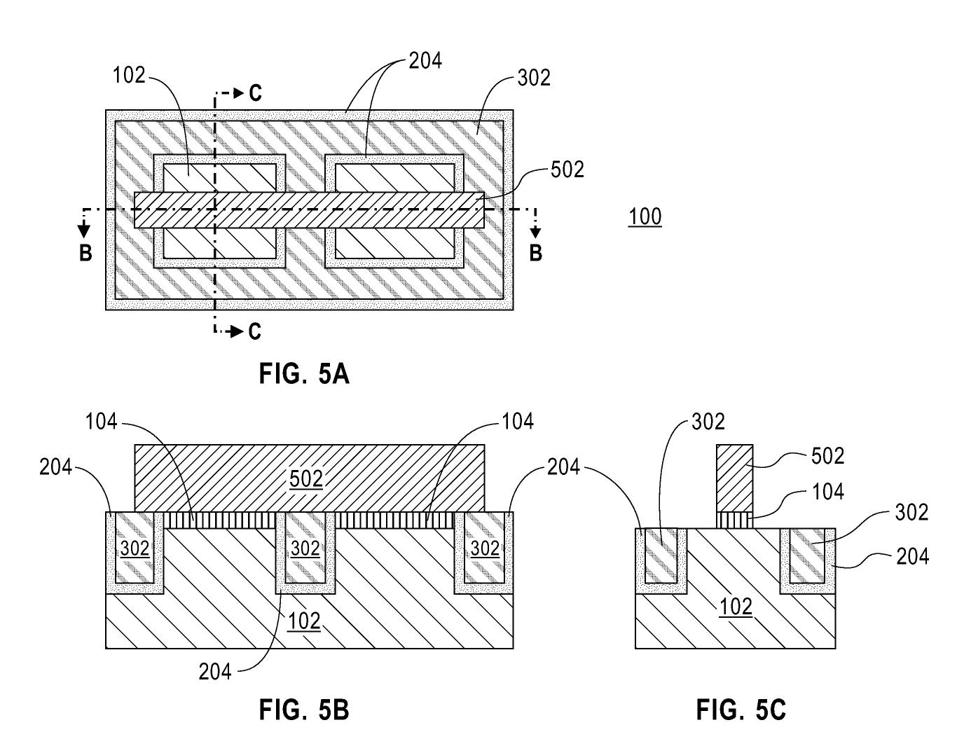

In FIG. 2, the shallow trench isolation (STI) 202 is defined. The dimensions of the trench formed are relevant to the size of the device 100 and highly dependent on the technology for which the device 100 is being used, for example SRAMs, microprocessors, and the like. In this illustration, a cross sectional view of the 3-dimensional rectangular device is shown, and the shallow trench isolation surrounds the device 100. In addition, the shallow trench isolation bisects the device 100 by a trench extending from one long side to its opposite side. Referring now to FIG. 5a, a top view of the device in a later manufacturing stage is illustrated with the layout of the shallow trench isolation 202 clearly shown. Generally, the trench is etched into the previously described stack: the pad film, the high-k material, and into the substrate, stopping at a pre-determined depth.

As illustrated in FIG. 2, the isolation trench can be formed by selectively removing portions of the pad film 106, the high-k material 104 and the substrate 102. In an embodiment, the shallow trench isolation is formed by known techniques of lithography, masking and etching steps. FIG. 2 depicts the semiconductor block after completion of these steps. In other embodiments, the semiconductor block can comprise more than a substrate, high-k material and pad film. In these cases the additional layers would be removed similar to how the pad film 106, high-k material 104 and substrate 102 are removed. Notably, in an embodiment that uses an SOI as substrate 102, the trench extends past the semiconductor material and into the insulator material of the SOI substrate 102, stopping at a pre-determined depth.

This example continues by lining the isolation trench 202 with a liner material 204. Liner material 204 is deposited on the sidewalls of isolation trench 202 as well as the bottom of isolation trench 202 so that all surfaces are coated with the liner material 204.

Any suitable technique can be used to deposit liner material 204 on the sidewalls and bottom of isolation trench 202, including CVD, LPCVD, plasma enhanced CVD (PECVD), and ALD. In alternative embodiments, liner material 204 can be thermally grown.

Liner material 204 is a material that prevents oxygen diffusion into the high-k material 104 from a later added dielectric material, thereby preserving the characteristics of the high-k material by forming an oxygen diffusion barrier. In an embodiment, the liner material 204 is a nitride. More specifically, the liner material 204 can be silicon nitride. Liner material 204 is deposited to an overall thickness in a range of about 2-25 nanometers for maximum effectiveness.

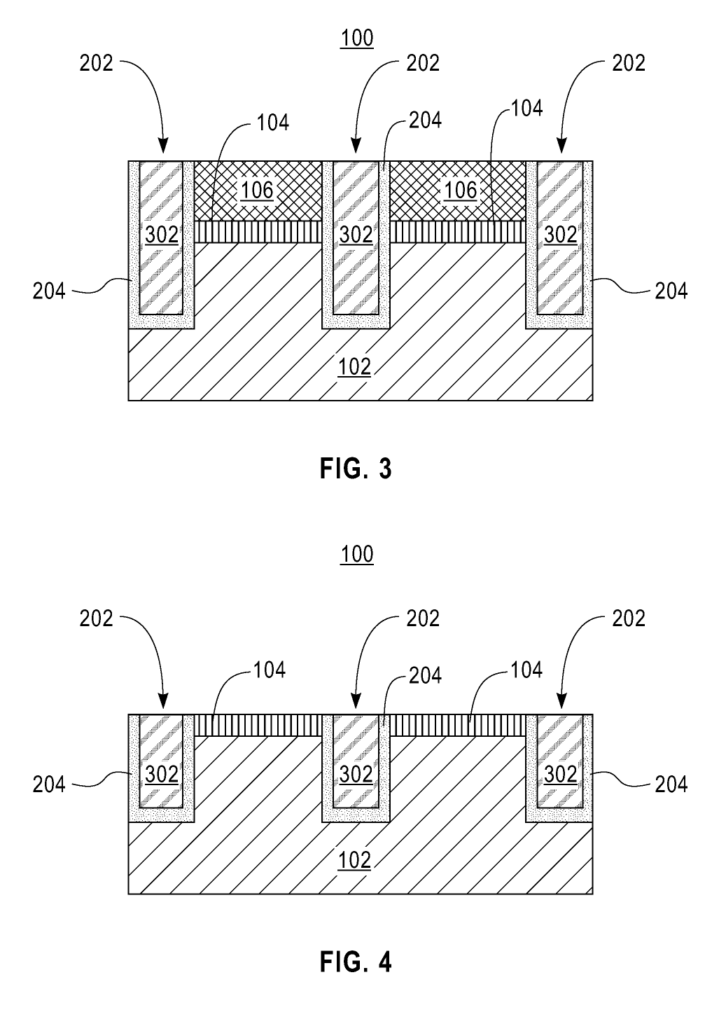

Referring now to FIG. 3, the shallow trench 202 is filled with an insulating dielectric material 302. In some embodiments, the dielectric material is overfilled, so that the shallow trench 202 is completely filled and a layer of dielectric material also overflows on top of the pad film 106. FIG. 3 depicts the device in a state after the overflow material has been removed. The dielectric material is deposited using any number of known techniques so that the shallow trench 202 is reliably filled, including CVD, sub atmospheric pressure CVD (SACVD), and spin-on. In an embodiment, the dielectric material 302 is an oxide-based material, such as silicon dioxide and the like.

At this stage of the process the dielectric material 302 now creates a filled trench 202 in the semiconductor substrate 102. Thereafter, the shallow trench is planarized using, for example, chemical mechanical polishing (CMP). The dielectric material 302 is removed to a level that corresponds to about the level of the liner material 204, as depicted in FIG. 3. After performing the CMP, the semiconductor device is left with a continuous surface, with the top surface of the dielectric material 302 continuous with the exposed liner material 204 surface and the surface of the pad film 106.

Although other steps of processes may be performed after the CMP is performed, this embodiment continues by recessing the STI and stripping the pad film 106. The end result of this step is illustrated in FIG. 4.

In an embodiment, the dielectric material 302 is recessed next by a wet etch. This can be done, for example by a buffered HF etch. This etching step also removes any residual oxide material still residing on top of the pad film from previous steps. This process is controlled so that the oxide is recessed to a depth that is about level with the top surface of the high-k material 104, still separated by the liner so that no contact between the high-k material 104 and dielectric material 302 occurs. After completion of this etching, the level of the dielectric material and the level of the high-k material are equalized. After completion of this etching step, the pad film 106 and liner material 204 are still fully present.

In the next step, the pad film 106 is stripped. To remove the pad film, a selective etch process can be used in a highly controllable manner so that the pad film is completely removed and the surface of the high-k material 104 is exposed. Also in this step, the nitride liner is recessed to a height that is level with the top surface of the high-k material 104, so that this etching step equalizes said liner and high-k dielectric levels. This process is tightly controlled, for example by a timed etch, so that the liner is etched to a height that is level with the high-k material and not any further, maintaining the integrity of the high-k material by preventing any contact with the dielectric material 302. This is illustrated in FIG. 4, where the high-k material 104 is clearly still separated from the dielectric material 302 by a segment of the liner 204. At the conclusion of these processing steps, FIG. 4 shows the high-k material 104, the liner 204 and the dielectric material 302 in a continuous plane. In an embodiment, a hot phosphoric acid strip is used as the etchant. In an embodiment, the pad film 106 and the liner 204 are both a nitride material, so that the same etch process can be used for both.

Although other steps or processes can be performed after the completion of the aforementioned steps, this embodiment continues with the formation of a metal gate by a replacement gate process. The first step of this process is to form a dummy gate, where the dummy gate is deposited as a placeholder, and will later be removed to make room for the metal gate. FIGS. 5a-5c illustrates the device with a dummy gate 502 formed by known techniques of deposition and patterning. In various embodiments, the dummy gate can be polysilicon, doped polysilicon, and the like.

In an alternative embodiment, the metal gate can be formed by a gate-first process.

To form a pattern as shown in FIG. 5a, dummy gate material is first deposited over the device. Next, a patterned resist etch can be done. In an embodiment, this can remove sections of the dummy gate and the high-k material to form a pattern as shown in FIG. 5a. In other embodiments, other patterns can be used to achieve desired results depending on the desired application.

FIG. 5a is a top view of the device so far, showing the layout of the example embodiment illustrated. By examining FIG. 5a, the full extent of the trench in this embodiment can be seen. Note that the dimensions shown are not to scale and that the device can have a layout that appears substantially different from that shown.

FIG. 5b is a sectional view of the same device. By observing FIG. 5b, it is again illustrated that the high-k material 104 is separated from the dielectric material 302 by a liner material 204, and at no point in the process have the two materials come in contact.

FIG. 5c is another sectional view that shows the device. By observing FIG. 5c, this embodiment illustrates a pattern that can be formed by the previous pattern resist etch.

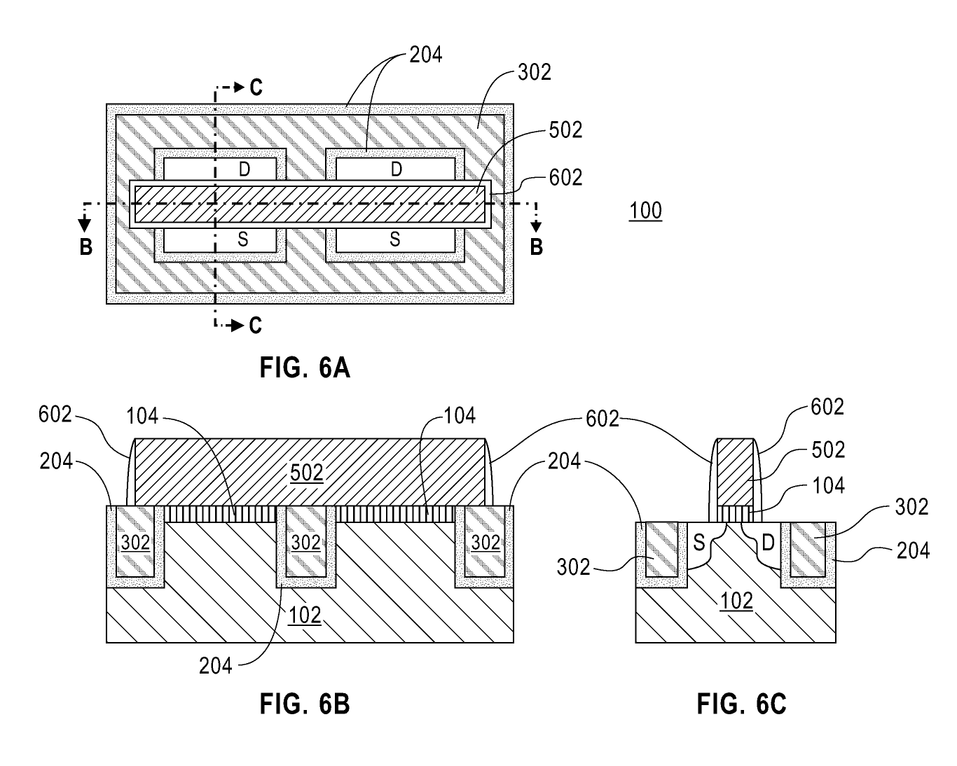

Although other steps or processes can be performed after the completion of the aforementioned steps, this embodiment continues with the formation of a spacer. To form the spacer 602, as seen in FIGS. 6a-6c, a conformal layer of spacer material is applied over the entire dummy gate 502, including the entire length of the sidewalls. In the same process step, the spacer material is applied over any other exposed portion of the device. In an embodiment, the conformal layer of spacer material is silicon nitride. The spacer material can be deposited by any number of known techniques, including CVD, LPCVD, PECVD, and the like.

In a next processing step, the spacer material 602 is etched by an anisotropic etch to remove any spacer material from the top of the dummy gate 502, from the liner 204, and from the dielectric material 302, and from most of the top of the substrate except immediately next to any side of the dummy gate 502. In an embodiment, this anisotropic etch is done by Plasma Reactive Ion (RIE) Etching. This is a highly directional etching process where the ions are normal to the surface (a preferred direction) which facilitates the removal of silicon nitride from the horizontal surfaces but mostly leaves a layer on the vertical surfaces. This leads to the formation of a spacer 602 on the sides of the dummy gate 502, as illustrated in FIGS. 6a-6c.

In this embodiment, source/drain regions are formed in the substrate at this stage of manufacturing. This can be done by known methods, for example by implantation and annealing. For example, this ion implantation process can dope a region with a P-type dopant or an N-type dopant, depending on the desired semiconductor device. An anneal cycle can be used to activate the dopants from the ion implementation process.

FIG. 6a illustrates an overhead view of the device so far. In FIG. 6a, the spacer 602 is seen surrounding the dummy gate 502 on all sides. Also visible in the overhead view of this embodiment are the relative locations of the source and drain regions, labeled ‘S’ and D: respectively. FIGS. 6b and 6c illustrate sectional views of this embodiment, and also illustrate that the spacer 602 is slightly tapered at the top due to the deposition and etching technique used to apply it. FIG. 6c also illustrates the source/drain regions of this embodiment.

Although other steps or processes can be performed after the completion of the aforementioned steps, this embodiment continues with depositing a dielectric 702 on the device. The dielectric material is deposited using any number of known techniques so that all exposed surfaces are covered. The methods used to deposit the dielectric material can include CVD, SACVD, spin-on, and the like. In some embodiments, the dielectric material 302 is an oxide-based material, such as silicon dioxide and the like.

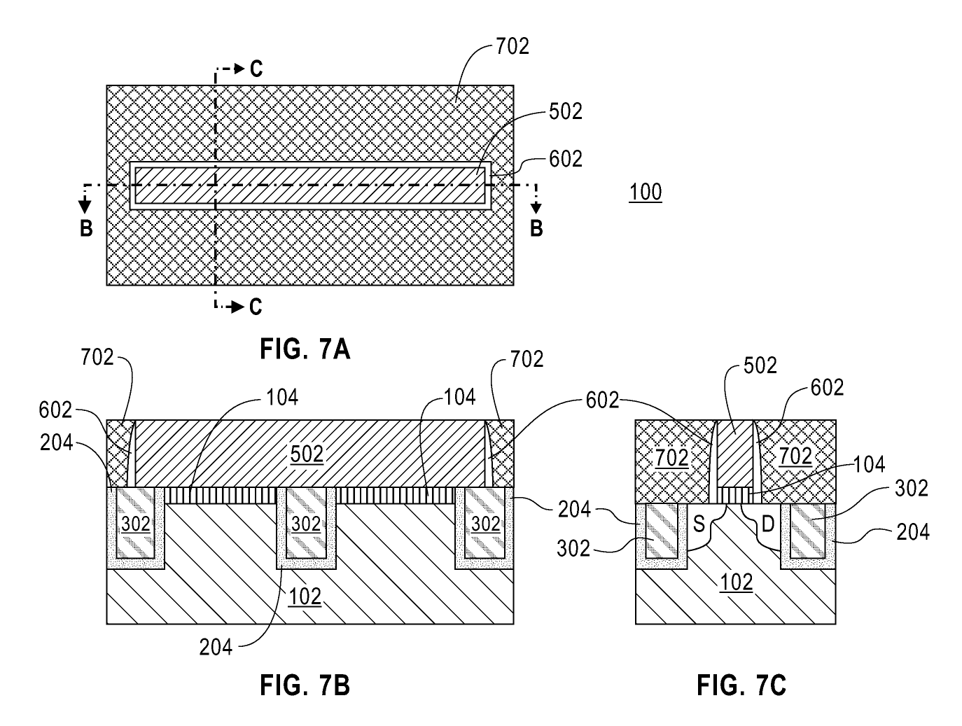

FIGS. 7a-c illustrate the device after a dielectric material has been deposited over all surfaces and subsequently planarized. The device is planarized to the level of the top of the dummy gate using, for example, CMP. FIG. 7a illustrates an overhead view of the device after a dielectric is deposited and subsequently planarized. FIGS. 7b and 7c are sectional views of the device at this manufacturing stage.

Although other steps or processes can be performed after the completion of the aforementioned steps, this embodiment continues with removing the dummy gate. This can be done by a wet etch, which can remove the polysilicon dummy gate selective to the oxide material. In an embodiment, potassium hydroxide (KOH) can be used for this purpose.

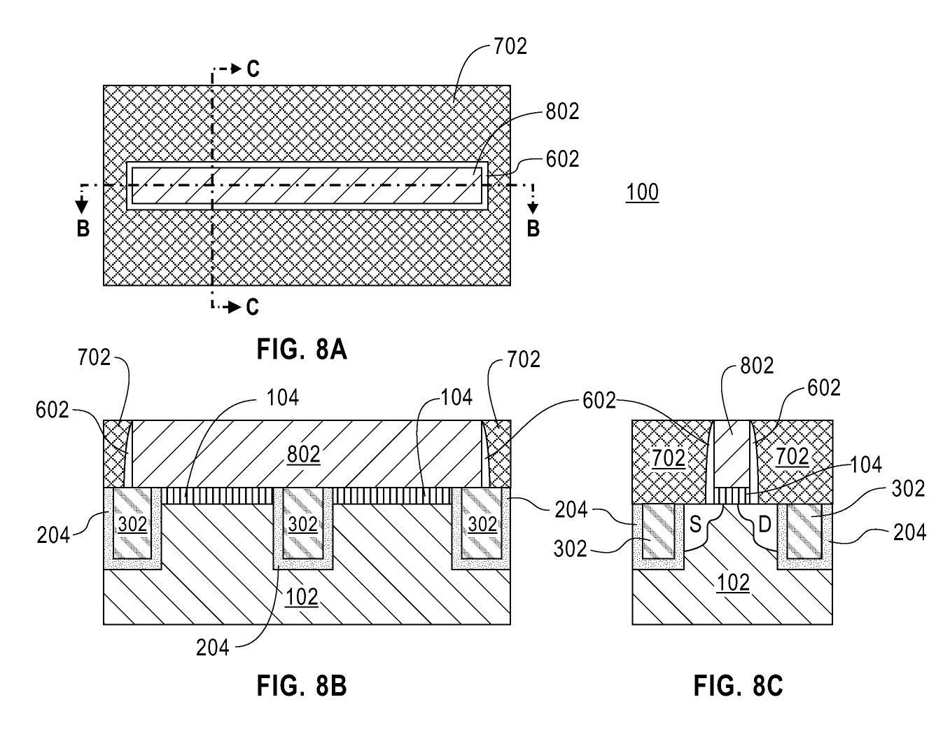

In a next manufacturing step, the void left by the removal of the dummy gate is filled with a gate conductor, 802, as illustrated in FIGS. 8a-8c. In an embodiment, this forms a metal gate. In various embodiments, different devices can be filled with different metals to achieve different workfunctions. The desired workfunction is dependent on the desired function of the device, and therefore will vary widely depending on the device. For example, an nMOS transistor and a pMOS transistor would use different metals for their metal gates, each with their own workfunction. The gate conductor 802 can include multiple different layered metals to form a metal gate.

The method as described above is used in the fabrication of integrated circuit chips. In an embodiment, the metal gates on each of multiple fabricated the field effect transistors are electrically connected to form an integrated circuit.

After completion of the previous manufacturing steps, a semiconductor device is produced. FIGS. 8a-8c are illustrations of the final product produced using this method. As seen in FIG. 8b, the semiconductor device has a substrate 102 and a high-k material 104 overlying the substrate. Etched into the high-k 104 and substrate 102 are isolation trenches filled with a dielectric 302 and lined by a liner material 204. Because the isolation trenches are etched into the high-k material 104 and subsequently lined, the dielectric 302 is completely blocked by the liner 204 from contact with the high-k material 104.

The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

While the present invention has been described with reference to what are presently considered to be the preferred embodiments, it is to be understood that the invention is not limited to the disclosed embodiments. On the contrary, the invention is intended to cover various modifications and equivalent arrangements included within the spirit and scope of the appended claims. The scope of the following claims is to be accorded the broadest interpretation so as to encompass all such modifications and equivalent structures and functions.

What is claimed is:

1. A method of manufacturing a semiconductor device, the method comprising:
depositing a high-k dielectric and a pad layer on a substrate having semiconductor material, resulting in a stack;
forming an isolation trench in said stack;
lining said isolation trench sidewalls with a material that forms an oxygen diffusion barrier;
filling said lined isolation trenches with a first dielectric material;
etching said first dielectric material to equalize the remaining first dielectric material and high-k dielectric levels;
etching said pad film and said isolation trench liner to completely remove the pad film and equalize said liner and high-k dielectric levels; and
forming a metal gate overlying at least a portion of said high-k dielectric and said first dielectric material.

2. The method according to claim 1, wherein said metal gate is formed by a replacement gate process.

3. The method according to claim 2, wherein said replacement gate process comprises:
depositing a dummy gate material on top of said semiconductor device;
patterning said dummy gate material and said high-k material to form gates;
surrounding said dummy gate with a spacer on all dummy gate sidewalls;
depositing a second dielectric material over said semiconductor device;
polishing said second dielectric material, stopping at said dummy gate level;
removing said dummy gate; and
refilling said dummy gate region with a metal gate material.

4. The method according to claim 3, wherein said dummy gate material is polysilicon.

5. The method according to claim 1, wherein said semiconductor substrate is selected from the group consisting of: bulk semiconductor, SOI, and strained SOI.

6. The method according to claim 1, wherein the step of etching said pad film and said isolation trench is carried out simultaneously or sequentially.

7. The method according to claim 1, wherein said pad film and said isolation trench liner are silicon nitride.

8. The method according to claim 1, wherein said first dielectric material is silicon dioxide.

9. A semiconductor device comprising:
a semiconductor substrate;
a high-k dielectric deposited over said substrate;
a lined isolation trench etched into the layers of said high-k material and said semiconductor substrate and filled with a dielectric material;
wherein said lined isolation trench extends fully into said high-k dielectric and at least partially into said semiconductor substrate;
wherein said liner of said isolation trench is an oxygen diffusion barrier; and
wherein said high-k dielectric is separated from said dielectric material by said liner of said isolation trench.

10. The semiconductor device according to claim 9, further comprising:
a metal gate overlying at least a portion of said high-k material and said dielectric material that fills said lined isolation trench.

11. The semiconductor device according to claim 10, wherein said metal gate comprises more than one layered metal.

12. The semiconductor device according to claim 9, wherein said semiconductor substrate is selected from the group consisting of: bulk semiconductor, SOI, and strained SOI.

13. The semiconductor device according to claim 9, wherein said high-k dielectric comprises a plurality of high-k dielectric materials.

14. The semiconductor device according to claim 9, wherein said liner of said isolation trench liner is silicon ntiride.

15. The semiconductor device according to claim 9, wherein said dielectric material that fills said isolation trench is silicon dioxide.

16. An integrated circuit comprising:
at least two field effect transistors, each comprising: a semiconductor substrate; a high-k dielectric deposited over said substrate; a lined isolation trench etched into the layers of said high-k material and said semiconductor substrate and filled with a dielectric material; wherein said lined isolation trench extends fully into said high-k dielectric and at least partially into said semiconductor substrate; wherein said liner of said isolation trench is an oxygen diffusion barrier; and wherein said high-k dielectric is separated from said dielectric material by said liner of said isolation trench; and
a metal gate on each of the said field effect transistors;
wherein said metal gates on each of the said field effect transistors are electrically connected to form said integrated circuit.

17. The integrated circuit according to claim 16, wherein said semiconductor substrate is selected from the group consisting of: bulk semiconductor, SOI, and strained SOI.

18. The integrated circuit according to claim 16, wherein said high-k dielectric comprises a plurality of high-k dielectric materials.

19. The integrated circuit according to claim 16, wherein said liner of said isolation trench liner is silicon nitride.

20. The integrated circuit according to claim 16, wherein said dielectric material that fills said isolation trench is silicon dioxide.
